(19) United States
(12) Patent Application Publication
(10) Pub. No.: US 2018/0076757 A1
(43) Pub. Date: Mar. 15, 2018

(54) SOLAR PANEL TRACKING ASSEMBLY

(71) Applicant: EDISUN MICROGRIDS, INC., Pasadena, CA (US)

(72) Inventors: William Gross, Pasadena, CA (US); Nikolai Syssoev, Canoga Park, CA (US); William Harwood, Valencia, CA (US); Herach Ayvazian, Pasadena, CA (US); Carl Chin, Pasadena, CA (US)

(21) Appl. No.: 15/697,310

(22) Filed: Sep. 6, 2017

Related U.S. Application Data
(60) Provisional application No. 62/385,729, filed on Sep. 9, 2016.
(60) Provisional application No. 62/385,847, filed on Sep. 9, 2016.

(51) Int. Cl. H02S 20/32; H02S 20/23; H02S 20/10; H01L 31/042; H01L 31/048

(52) U.S. Cl. CPC H02S 20/32; H02S 20/23; H01L 31/048; H01L 31/042; H02S 20/10

(57) ABSTRACT

A solar energy tracking assembly for a solar energy panel can include a frame that supports the solar energy panel and pivots the solar energy panel between a retracted position generally parallel to a support surface on which the tracking assembly rests and an upright position. The frame can include a circular track on which the solar energy panel rotates about an axis of the circular track. The circular track is supported by a combination of support beam and footings that both bear the force of the solar panel as well as bear the torsional force from wind loading on the solar panel.

### INCORPORATION BY REFERENCE TO ANY PRIORITY APPLICATIONS

Any and all applications for which a foreign or domestic priority claim is identified in the Application Data Sheet as filed with the present application are hereby incorporated by reference under 37 CFR 1.57.

### BACKGROUND OF THE INVENTION

### Field

The present invention is directed to a solar energy tracking array, and more particularly to aspects of a solar energy tracking assembly.

### Description of the Related Art

Different solar energy system designs, such as photovoltaic systems and concentrated solar power systems, exist. However, existing solar energy systems suffer from various drawbacks. For example, many existing systems are industrial in scale, bulky and difficult to transport. Existing systems are also costly and complex, and require a lot of manpower to install.

### SUMMARY

There is a need for modular solar energy systems that are more compact, less costly and easier to install. The invention addresses these requirements with a solar energy tracking assembly that includes an actuator housing with actuators that rotate a solar panel, mirror, or lens in a horizontal plane relative to a mounting surface and also in a vertical plane relative to the actuator housing. The actuators preferably include motors that are arranged co-axially in the actuator housing to provide a compact and cost-effective module. In some embodiments, the actuator housing further includes a tracking controller and a tracking controller housing that is configured to serve as a stop for the solar panel, mirror or lens. When in the stowed position, for example, the solar panel, mirror, or lens is configured to contact the tracking controller housing and lie flat, thereby preventing the wind from exerting a torque on the solar energy tracking assembly. In some embodiments, the solar energy tracking assembly further includes torsion springs, preferably two co-axial torsion springs, configured to provide a biasing force that tilts up the solar panel, mirror, or lens, thereby requiring a lower-power or less expensive actuator to regular the elevation angle.

### BRIEF DESCRIPTION OF THE DRAWINGS

FIG. 1 is a rear perspective view of one embodiment of a solar energy panel tracking array.

FIG. 2 is a front view of a portion of the solar energy panel tracking array of FIG. 1.

FIG. 3 is a side view of a portion of the solar energy panel tracking array of FIG. 1

FIG. 4 is a rear perspective view of one embodiment of a solar energy panel tracking assembly shown in the array of FIG. 1.

FIG. 5a is a perspective view of torsion spring used in the solar energy panel tracking assembly of FIG. 4.

FIG. 5b is a close up perspective view of a portion of the torsion spring used in the solar energy panel tracking assembly of FIG. 4.

FIG. 5c is a close up perspective view of the torsion spring used in the solar energy panel tracking assembly of FIG. 4.

FIG. 6 is a front view of the solar energy panel tracking assembly of FIG. 4.

FIG. 7 is a side view of the solar energy panel tracking assembly of FIG. 4.

FIG. 8 is a perspective view of the solar energy panel tracking assembly of FIG. 4.

FIG. 9 is a side view of a portion of the solar energy panel tracking assembly of FIG. 4.

### DETAILED DESCRIPTION

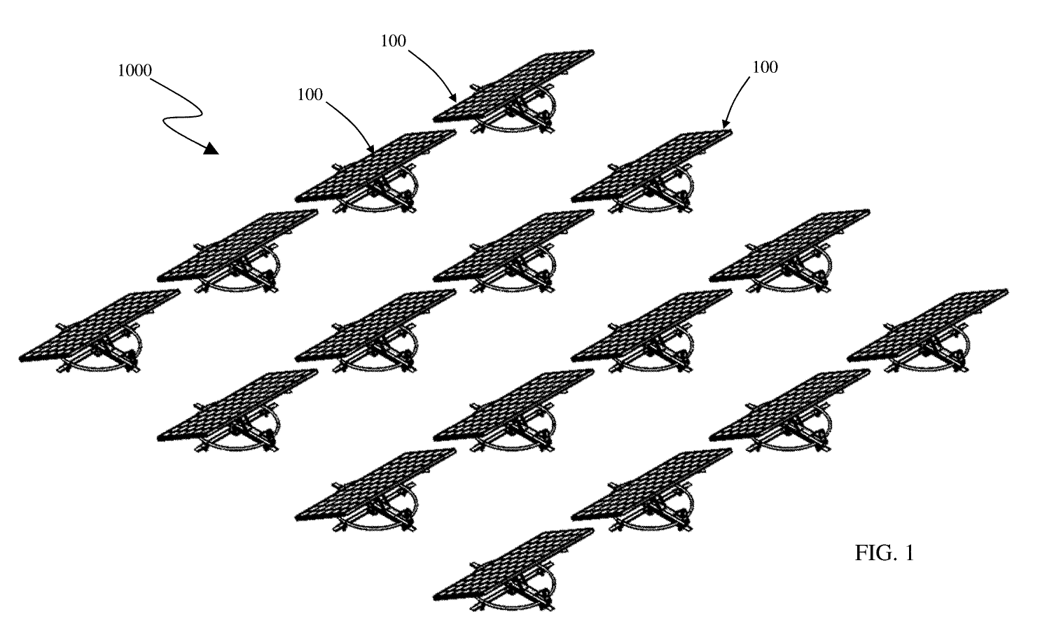

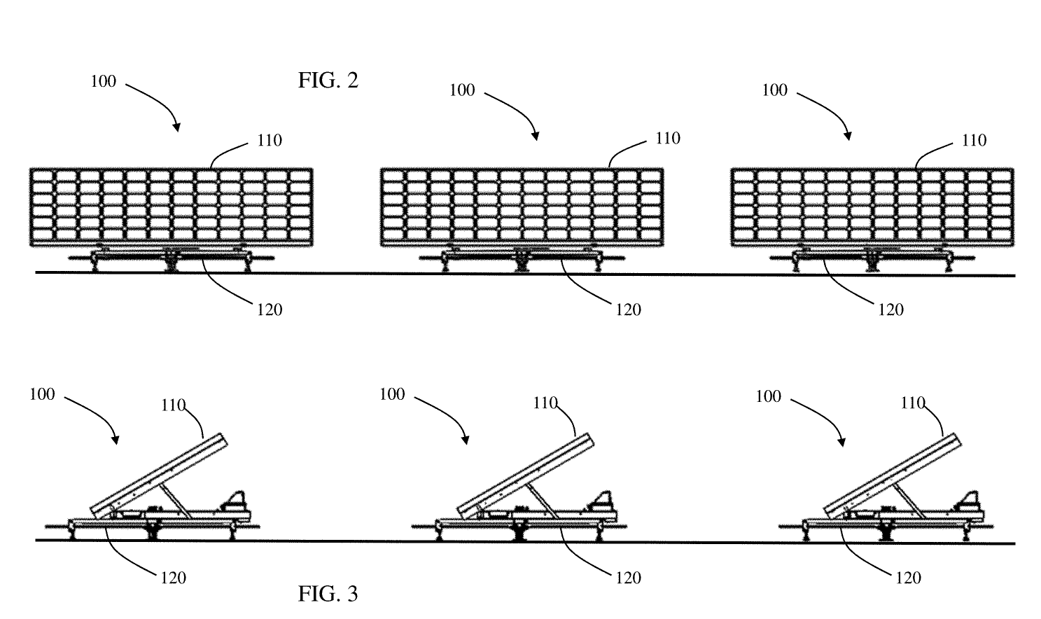

FIGS. 1-3 show one embodiment of a solar energy panel array 1000 that can be mounted on a support surface (e.g., a ground surface, a roof of a building or parking structure). The array 1000 can have a plurality of solar energy tracking assemblies 100 arranged over an area. In the illustrated embodiment, the plurality of assemblies 100 in the array 1000 are arranged in multiple rows R, with the assemblies 100 in one row R aligned with the assemblies 100 in adjacent rows R to define columns C that extend in a direction generally perpendicular to the direction of the rows R. In other embodiments, the plurality of assemblies 100 can be arranged in another suitable pattern. For example, in one embodiment, the plurality of assemblies 100 can be arranged in a hexagonal pattern, where each tracking assembly 100 is surrounded by six other assemblies 100. In the illustrated embodiment, each tracking assembly 100 includes a solar energy panel, preferably a photovoltaic panel.

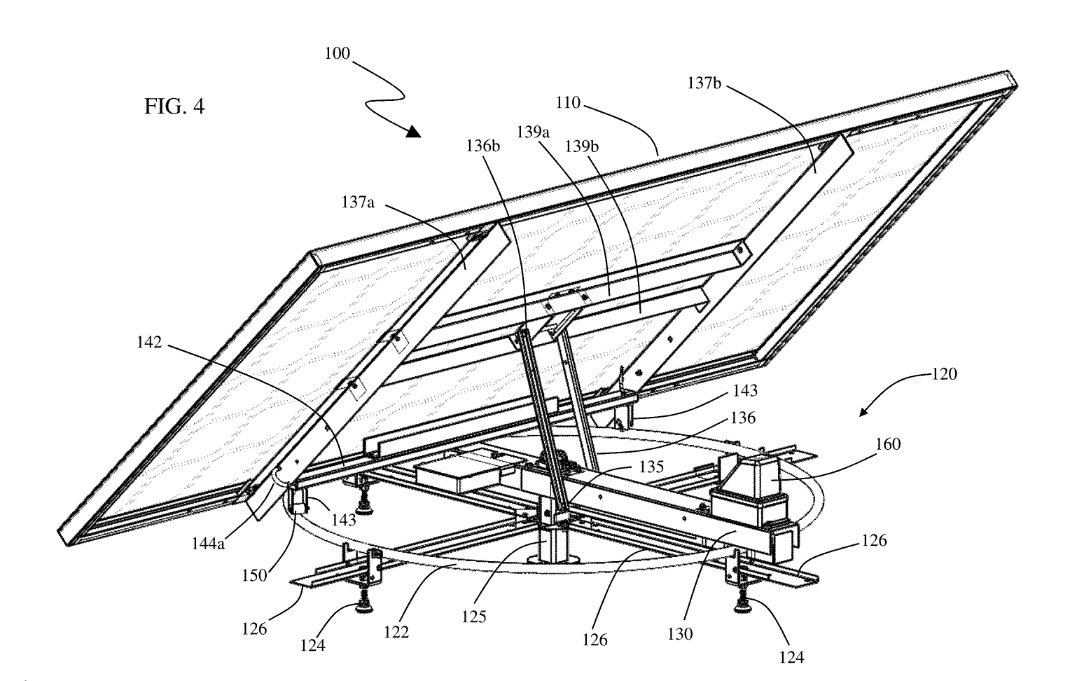

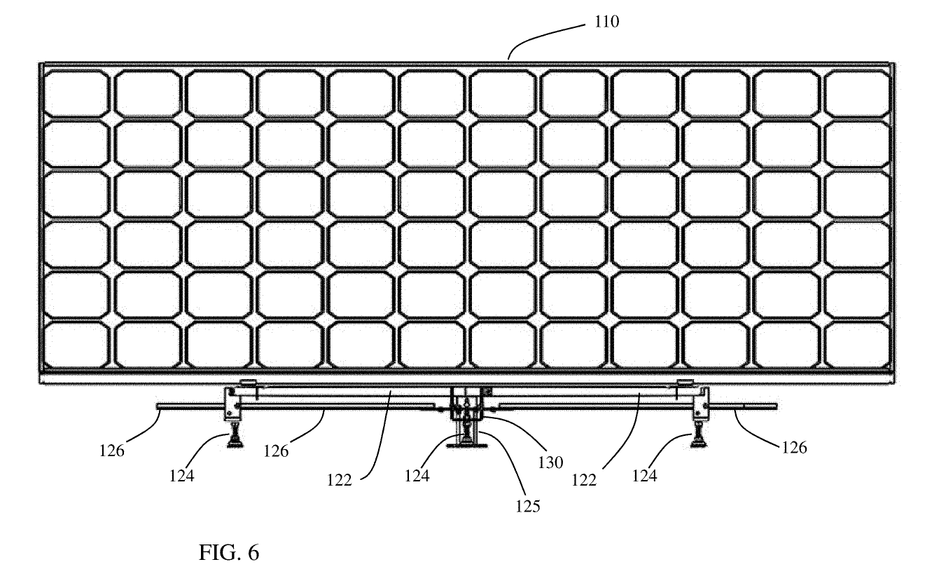

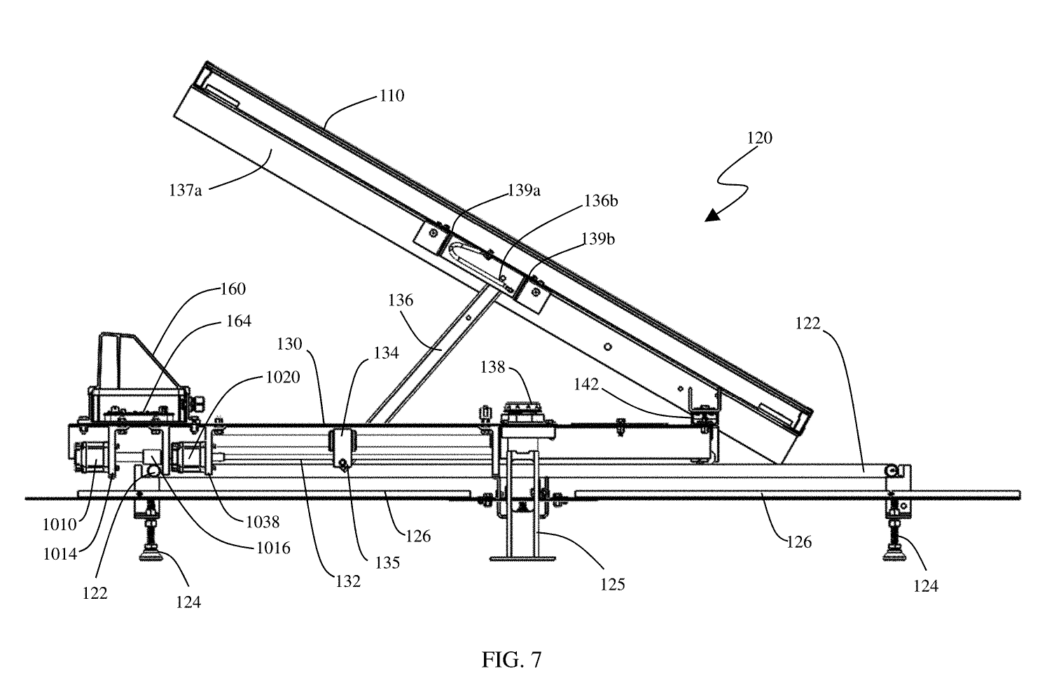

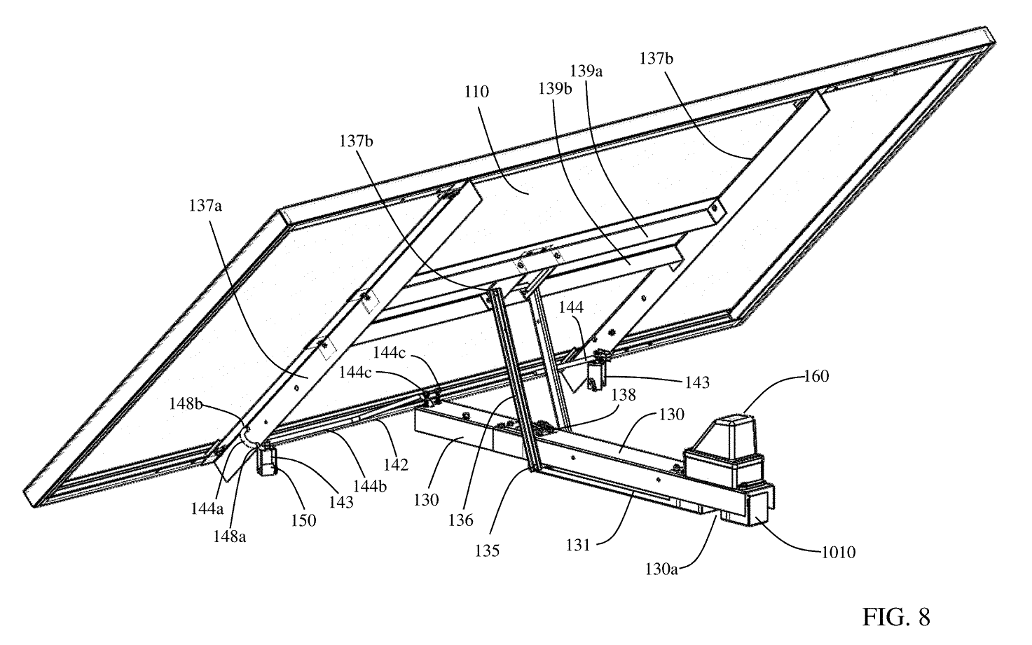

FIGS. 4-9 show one embodiment of a solar energy tracking assembly 100, which can support a solar energy panel 110. In the illustrated embodiment, the solar energy panel 110 is a photovoltaic panel. In another embodiment, the solar energy panel 110 can be a mirror or lens.

The solar energy tracking assembly 100 includes a frame assembly 120 that movably supports the solar energy panel 110. The frame 120 can include a carousel or track 122 that is supported by a support beam 126 and one or more support feet 124, 125 (e.g., supported off a ground or support surface). In the illustrated embodiment, the track 122 can optionally be circular in shape. The support beam 126 may extend under the track 122 to one or more optional ballast weights (e.g., concrete blocks) that retain the assembly 100 in a generally fixed position on the support surface (e.g., ground surface, roof of a parking structure or building). In this configuration, the support beams 126 bear the majority of the weight of the track 122 and the panel 110, while the support feet 124, 125 prevent lateral rotation of the track 122 in order to stabilize the panel 110.

The solar energy tracking assembly 100 further includes an actuator housing 130 movably coupled to the track 122. In the illustrated embodiment, the actuator housing 130 can have a recess or an opening 130a and a wheel 1016. The track 122 extends through the opening 130a and optionally contacts the wheel 1016 mounted in the actuator housing 130. The actuator housing 130 can also be pivotally coupled to the support beam 126 via a pin 138 so that the actuator housing 130 rotates in a circle as the wheel 1016 turns. In one embodiment, the pin 138 is generally located at a radial center of the track 122 (e.g., at a center point through which a vertical axis of the track 122 is defined).

The actuator housing 130 can include a first actuator 1010 that drives the rotation of the actuator housing 130 (together with the solar energy panel 110 about a vertical axis), and a second actuator 1020 that drives the tilting of the solar energy panel 110 relative to the ground or support surface on which the tracking assembly 100 rests. In one embodiment, the same actuator drives the rotation of the housing 130 on the track 122 (e.g. to adjust the azimuth angle) and the tilting of the solar energy panel 110 (e.g., to adjust the elevation angle). The actuator housing 130 can optionally have longitudinal openings or slots 131 on opposite sides of the actuator housing 130. In the illustrated embodiment, pins 135 can optionally extend through the openings 131 on both sides of the actuator housing 130 and those pins 135 couple to a nut member 134 that is driven along the longitudinal axis of the actuator housing 130 via rotation of a lead screw 132. The pins 135 can couple to one end of support members 136, where the opposite ends of the support members 136 are pivotally coupled to cross bars 139a, 139b that support the solar energy panel 110. The cross bars 139a, 139b can couple to a pair of support members 137a, 137b that extend generally perpendicular to the cross bars 139a, 139b and support the solar energy panel 110 without distortion of the panel 110. As the nut member 134 is driven proximally by rotation of the lead screw 132 toward opening 130a of the actuator housing 130, the solar energy panel 110 is pivoted downward toward a position parallel with the ground or mounting surface. Alternatively, as the nut member 134 is driven distally by rotation of the lead screw 132 away from opening 130a of the actuator housing 130, the solar energy panel 110 is pivoted upward toward an upright position relative to the ground surface. In other embodiments, other suitable mechanisms (other than a lead screw mechanism) can be used to drive the pivoting of the solar energy panel 110.

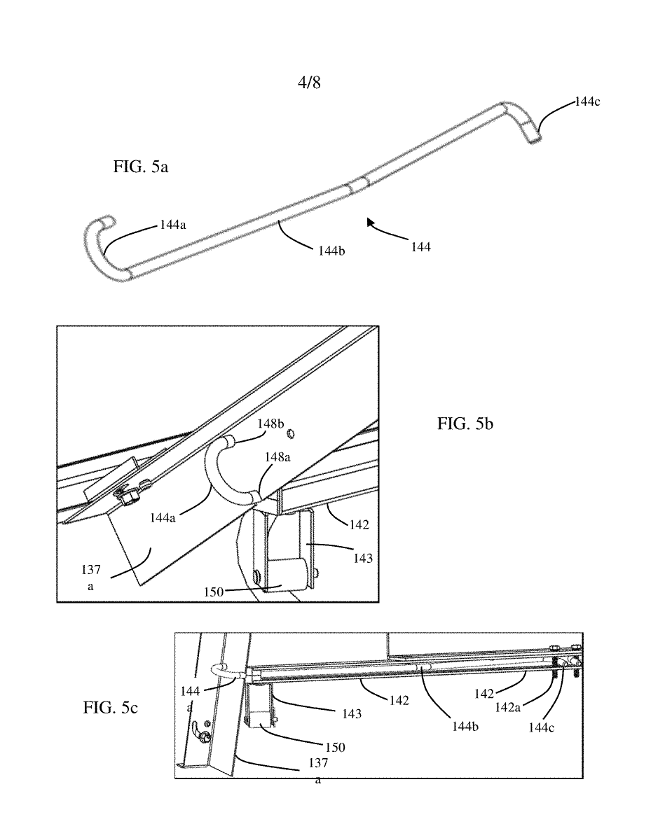

With continued reference to FIGS. 4-9, The frame assembly 120 can include a hinge assembly that can includes a spring housing 142 that extends generally parallel to the cross bars 139a, 139b. The housing 142 can be a square tube having an open channel thorough which two torsion springs 144 (see FIG. 5a) extend. Each torsion spring 144 includes a distal curved end portion 144a, a linear portion 144b, and a proximal bent portion 144c. The housing 142 can be affixed to an end of the actuator housing 130 with one of more fasteners 142a. The torsion springs 144 can optionally extend generally co-planar and co-linear with each other and can each have a distal curved end portion 144a that is affixed to the support members 137a, 137b to thereby couple the housing 142 to the support members 137a, 137b. In the illustrated embodiment, the curved end portions 144a can extend through an opening 148a in support members 137a, 137b and can have distal ends 144a that curve about 180 degrees and extend back into the support members via apertures or holes 148b to anchor the orientation of the curved end portions 144a support members 137a, 137b and define a hinged connection. That is, the linear portions 144b of the torsion springs 144 serve as an axle or a pivot about which the panel 110 physically rotates when the elevation angle of the panel is changed. In one embodiment, the bend defined by the curved end portions 144a between the opening 148a and the hole 148b of each bracket 137a, 137b has a radius of about 1 inch. However, in other embodiments, such a bend can have other suitable radius values.

The torsion springs 144 can have a generally linear portion 144b that extend toward a center of the housing 142. The linear portions 144b transition to proximal bent portions 144c. In one embodiment, the proximal bent portions 144c are bent generally at 90 degrees relative to the generally linear portions 144b, and have a length of about 1½ inches. In one embodiment the proximal bent portions 144c contact and bear against an inner surface of the channel of the housing 142 to inhibit (e.g., prevent) the proximal bent portions 144c from rotating relative to the housing 142 as the solar energy panel 110 is pivoted upward and/or downward relative to a ground plane. However, in other embodiments, the proximal bent portions 144c can be bent at other suitable angles (e.g., less than 90 degrees or more than 90 degrees relative to the generally linear portions 144b) and have other suitable lengths (e.g., longer than 1½ inches or shorter than 1½ inches). In one embodiment, the length of the proximal bent portions 144c is approximately equal to the effective diameter of the housing 142. In another embodiment, the proximal bent portions 144c extend through openings in a wall of the housing 142 to substantially fix an orientation of the proximal bent portions 144c relative to the housing 142.

The distal curved end portions 144a of the torsion springs 144 can pivot or rotate relative to the proximal bent portions 144c as the linear portions 144b axially bent in response to the solar energy panel 110 pivoting upward or downward. The housing 142 can be supported on the track 122 by a pair of wheels 150, each attached to the housing 142 by a bracket assembly 143. Accordingly, rotational support of the solar energy panel 110 on the track 122 can be provided via three contact points, namely via the wheel 1016 in opening 130a of the actuator housing 130 and the pair of wheels 150.

The torsion springs 144 can optionally be made of metal. In one embodiment, the torsion springs 144 can be made of stainless steel (e.g., spring grade stainless steel. However, in other embodiments the torsion springs 144 can be made of other suitable materials, such as other suitable metals or polymer materials. Optionally, the torsion springs 144 can be shaped like rods and have a diameter of between about 0.15 inches and about 0.5 inches, in some embodiments about 0.25 inches. However, in other embodiments, the diameter can be smaller or larger than these values.

In operation, the torsion springs 144 apply a bias force against the support members 137a, 137b via the inner channel of the housing 142, to thereby bias the solar energy panel 110 toward the upward orientation. Accordingly, the bias force applied by the torsion springs 144 counteracts at least a portion of the weight of the solar energy panel 110 on the frame 120, to advantageously facilitate the pivoting of the solar energy panel 110 upward or downward. The torsion springs 144 can exert a relatively higher force on the solar energy panel 110 when the solar energy panel 110 is in a retracted position (e.g., generally parallel to a support surface of the solar energy tracking assembly 100). The torsion springs 144 can exert a relatively lower force on the solar energy panel 110 when the solar energy panel 110 is in a raised position (e.g., at approximately 45 degrees relative to the support surface of the solar energy tracking assembly 100). Such a bias force applied by the torsion springs 144 advantageously allows the actuator in the actuator housing 130 to utilize less power to pivot the solar energy panel 110 upward or toward an upright position. In one embodiment, the bias force applied by the torsion springs 144 allows for a smaller actuator, or actuator with a lower power rating, to be used to alter the elevation angle of the solar energy panel 110. Further, as discussed above the distal curved end portions 144a couple to the support members 137a, 137b. Accordingly, the torsion springs 144 also advantageously provide at least a portion of the hinged connection between the solar energy panel 110 and the track 122.

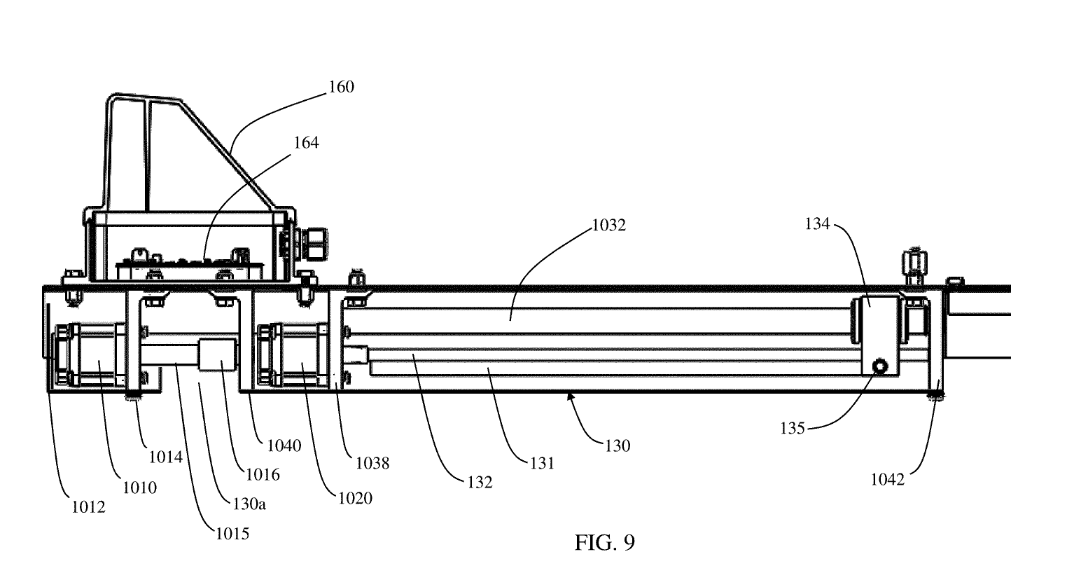

Illustrated in FIG. 9 is a side view of the interior of the actuator housing 130 that mounts on top of the carousel track 122. The housing 130 includes a plurality of actuators configured to adjust the azimuth and elevation angles of the panel 110. These actuators include a first motor 1010 and a second motor 1020 which are energized by a tracking controller 164 that maintains the solar panel 110 aimed at the sun. The first motor 1010, which is mounted between an endcap 1012 and a stationary bracket 1014, is configured to turn a shaft 1015 and a drive wheel 1016 that runs atop the carousel track 122 to rotate the panel 110 in the horizontal plane. The carousel track 122 seats within the recess or opening 130a to prevent the housing 130 from derailing. The second motor 1020, which is mounted to a stationary bracket 1038, drives a leadscrew 132 that rotates in a fixed position between the bracket 1038 and bracket 1040. As the leadscrew 132 turns, the nut block or nut member 134 translates left or right. Since the bottom of the support members 136 are affixed to the nut block 134, the translation of the nut block 134 also changes the elevation angle of the panel 110. To counteract the torque on the nut block 134 and maintain the proper orientation, the actuator housing 130 in the preferred embodiment includes at least one guide rod 1032 above the leadscrew 132 for the length of the leadscrew.

In the preferred embodiment, the tracking assembly 100 further includes a tracking controller 164 and a controller housing 160. The tracking controller 164 is configured to determine the orientation of the sun relative to the panel 110 and orient the panel 110 to either face the sun directly or to reflect light from the sun to an external receiver (not shown), for example. In particular, the tracking controller generates signals to the first motor 1010 and a second motor 1020 to energize the motors as require to alter the azimuth and elevation angles of the panel 110, respectively. During adverse weather conditions, however, the tracking controller 164 may also drive the panel 110 into a horizontal stow configuration. For purpose of stowing the panel, the height of the tracking controller housing 160, relative to the actuator housing 130, is configured so that the panel 110 lies flat when in contact with the tracking controller housing 160. In this manner, the panel 110 lies substantially parallel to the mounting surface (e.g., ground or roof) in order to prevent wind from exerting a torque on the panel 110 when in this stowed position.

While certain embodiments of the inventions have been described, these embodiments have been presented by way of example only, and are not intended to limit the scope of the disclosure. Indeed, the novel methods and systems described herein may be embodied in a variety of other forms. Furthermore, various omissions, substitutions and changes in the systems and methods described herein may be made without departing from the spirit of the disclosure. The accompanying claims and their equivalents are intended to cover such forms or modifications as would fall within the scope and spirit of the disclosure. Accordingly, the scope of the present inventions is defined only by reference to the appended claims.

Features, materials, characteristics, or groups described in conjunction with a particular aspect, embodiment, or example are to be understood to be applicable to any other aspect, embodiment or example described in this section or elsewhere in this specification unless incompatible therewith. All of the features disclosed in this specification (including any accompanying claims, abstract and drawings), and/or all of the steps of any method or process so disclosed, may be combined in any combination, except combinations where at least some of such features and/or steps are mutually exclusive. The protection is not restricted to the details of any foregoing embodiments. The protection extends to any novel one, or any novel combination, of the features disclosed in this specification (including any accompanying claims, abstract and drawings), or to any novel one, or any novel combination, of the steps of any method or process so disclosed.

Furthermore, certain features that are described in this disclosure in the context of separate implementations can also be implemented in combination in a single implementation. Conversely, various features that are described in the context of a single implementation can also be implemented in multiple implementations separately or in any suitable subcombination. Moreover, although features may be described above as acting in certain combinations, one or more features from a claimed combination can, in some cases, be excised from the combination, and the combination may be claimed as a subcombination or variation of a subcombination.

Moreover, while operations may be depicted in the drawings or described in the specification in a particular order, such operations need not be performed in the particular order shown or in sequential order, or that all operations be performed, to achieve desirable results. Other operations that are not depicted or described can be incorporated in the example methods and processes. For example, one or more additional operations can be performed before, after, simultaneously, or between any of the described operations. Further, the operations may be rearranged or reordered in other implementations. Those skilled in the art will appreciate that in some embodiments, the actual steps taken in the processes illustrated and/or disclosed may differ from those shown in the figures. Depending on the embodiment, certain of the steps described above may be removed, others may be added. Furthermore, the features and attributes of the specific embodiments disclosed above may be combined in different ways to form additional embodiments, all of which fall within the scope of the present disclosure. Also, the separation of various system components in the implementations described above should not be understood as requiring such separation in all implementations, and it should be understood that the described components and systems can generally be integrated together in a single product or packaged into multiple products.

For purposes of this disclosure, certain aspects, advantages, and novel features are described herein. Not necessarily all such advantages may be achieved in accordance with any particular embodiment. Thus, for example, those skilled in the art will recognize that the disclosure may be embodied or carried out in a manner that achieves one advantage or a group of advantages as taught herein without necessarily achieving other advantages as may be taught or suggested herein.

Conditional language, such as “can,” “could,” “might,” or “may,” unless specifically stated otherwise, or otherwise understood within the context as used, is generally intended to convey that certain embodiments include, while other embodiments do not include, certain features, elements, and/or steps. Thus, such conditional language is not generally intended to imply that features, elements, and/or steps are in any way required for one or more embodiments or that one or more embodiments necessarily include logic for deciding, with or without user input or prompting, whether these features, elements, and/or steps are included or are to be performed in any particular embodiment.

Conjunctive language such as the phrase “at least one of X, Y, and Z,” unless specifically stated otherwise, is otherwise understood with the context as used in general to convey that an item, term, etc. may be either X, Y, or Z. Thus, such conjunctive language is not generally intended to imply that certain embodiments require the presence of at least one of X, at least one of Y, and at least one of Z.

Language of degree used herein, such as the terms “approximately,” “about,” “generally,” and “substantially” as used herein represent a value, amount, or characteristic close to the stated value, amount, or characteristic that still performs a desired function or achieves a desired result. For example, the terms “approximately”, “about”, “generally,” and “substantially” may refer to an amount that is within less than 10% of, within less than 5% of, within less than 1% of, within less than 0.1% of, and within less than 0.01% of the stated amount. As another example, in certain embodiments, the terms “generally parallel” and “substantially parallel” refer to a value, amount, or characteristic that departs from exactly parallel by less than or equal to 15 degrees, 10 degrees, 5 degrees, 3 degrees, 1 degree, or 0.1 degree.

The scope of the present disclosure is not intended to be limited by the specific disclosures of preferred embodiments in this section or elsewhere in this specification, and may be defined by claims as presented in this section or elsewhere in this specification or as presented in the future. The language of the claims is to be interpreted broadly based on the language employed in the claims and not limited to the examples described in the present specification or during the prosecution of the application, which examples are to be construed as non-exclusive.

What is claimed is:

1. A solar energy tracking assembly, comprising:
a solar energy panel;
a frame configured to support the solar energy panel and to pivot the solar energy panel between a retracted position generally parallel to a support surface on which the tracking assembly rests and an upright position; and
a hinge assembly that operatively couples the solar energy panel to the frame, the hinge assembly comprising:
a pair of support members mounted to the solar energy panel;
a linear housing that extends between the pair of support members, and
a pair of torsion springs, each of the pair of torsion springs having a distal curved end portion coupled to one of the pair of support members, a proximal bent portion configured to contact an inner channel surface of the linear housing, and a generally linear portion that extends between the proximal bent portion and the distal curved end portion, the proximal bent portion extending in an opposite direction from the distal curved end portion relative to the generally linear portion,
wherein the pair of torsion springs are configured to apply a bias force against the solar energy panel to counteract at least a portion of a weight of the solar energy panel as it is pivoted between the retracted and upright positions, the bias force being relatively greater when the solar energy panel is in the retracted position and relatively lower when the solar energy panel is in the upright position.

2. The assembly of claim 1, wherein the linear housing is a square tube that at least partially houses the pair of torsion springs, wherein the distal curved end portions extend out of the ends of the linear housing and couple to the pair of support members attached to the solar energy panel at two locations.

3. The assembly of claim 2, wherein each distal curved end portion extends through an opening in the support member proximal an end of the linear housing, curves approximately 180 degrees and extends through an aperture in the support member that is proximal the solar energy panel, the aperture spaced apart from the opening in the bracket, and wherein the support member rotates about the opening as the solar energy panel is pivoted between the retracted and upright positions.

4. The assembly of claim 3, wherein at least a portion of the pair of torsion springs extend generally co-axial with each other.

5. The assembly of claim 1, wherein the proximal bent portions of the pair of torsion springs bear against the inner channel surface of the linear housing to inhibit rotation of the proximal bent portions within the linear housing.

6. The assembly of claim 5, wherein a length of the proximal bent portions is approximately equal to an equivalent diameter of the inner channel of the linear housing.

7. The assembly of claim 4, wherein the frame includes a circular track on which the solar energy panel is configured to rotate about an axis of the track, the hinge assembly supported on the circular track and interposed between the circular track and the solar energy panel.

8. A solar energy tracking assembly, comprising:
a solar energy panel;
a frame configured to support the solar energy panel and to pivot the solar energy panel between a retracted position generally parallel to a support surface on which the tracking assembly rests and an upright position, the frame comprising a carousel on which the solar energy panel is rotatably supported about an axis of the carousel;
an actuator housing; and
a hinge assembly that couples the actuator housing and the solar energy panel;
wherein the actuator housing comprises:
a first actuator for controlling an azimuth angle between the solar energy panel and the carousel, and
a second actuator for controlling an elevation angle between the solar energy panel and the carousel, wherein the first actuator and the second actuator are aligned linearly within the actuator housing.

9. The assembly of claim 8, wherein the first actuator is configured to turn a first wheel in contact with the carousel to rotate the solar energy panel about a vertical axis.

10. The assembly of claim 9, wherein the second actuator is configured to turn a lead screw that moves a nut member to rotate the solar energy panel about a horizontal axis.

11. The assembly of claim 10, wherein the first actuator comprises a first motor, and the second actuator comprises a second motor, and wherein the first motor and second motor are aligned in parallel in the actuator housing.

12. The assembly of claim 9, wherein the first wheel is mounted in an opening or recess configured to receive the carousel and maintain contact between the first wheel and the carousel.

13. The assembly of claim 12, further including a pair of wheels in contact with the carousel.

14. The assembly of claim 13, wherein the pair of wheels in contact with the carousel are attached to the hinge assembly.

15. A solar energy tracking assembly, comprising:
a solar energy panel;
a frame configured to support the solar energy panel and to pivot the solar energy panel between a retracted position generally parallel to a support surface on which the tracking assembly rests and an upright position, the frame comprising a carousel on which the solar energy panel is rotatably supported about an axis of the carousel;
an actuator housing;
a hinge assembly that couples the actuator housing and the solar energy panel; and
a tracking controller; and
a tracking controller housing configured to protectively conceal the tracking controller.

16. The assembly of claim 15, wherein the tracking controller housing is mounted on top of the actuator housing.

17. The assembly of claim 16, wherein the tracking controller housing is configured to make contact with a back of the solar energy panel.

18. The assembly of claim 17, wherein the solar energy panel is configured to lie substantially horizontal when the solar energy panel makes contact with the tracking controller housing.

19. The assembly of claim 18, wherein the solar energy panel is configured to lie substantially horizontal when the solar energy panel makes contact with the tracking controller housing in a stow configuration.

20. The assembly of claim 19, wherein stow configuration is configured to prevent wind from exerting a torque on the solar energy panel during adverse weather conditions.
